(19) United States
(12) Patent Application Publication
(10) Pub. No.: US 2015/0077948 A1
(43) Pub. Date: Mar. 19, 2015

(54) PRINTED CIRCUIT BOARD CONNECTION STRUCTURE

(71) Applicant: Olympus Corporation, Tokyo (JP)

(72) Inventor: KENJIRO KANNO, Tokyo (JP)

(21) Appl. No.: 14/453,941

(22) Filed: Aug. 7, 2014

Related U.S. Application Data
(63) Continuation of application No. PCT/JP2013/003958, filed on Jun. 25, 2013.

(30) Foreign Application Priority Data
Jun. 29, 2012 (JP) 2012-147329

(51) Int. Cl. H05K 1/14; H05K 1/02

(52) U.S. Cl. CPC H05K 1/14; H05K 1/0269; H05K 2201/05; H05K 2201/2072
USPC 361/749

(57) ABSTRACT

A printed circuit board connection structure is formed by clamping and connecting a first printed circuit board and a second printed circuit board, at least one of which is a flexible printed circuit board, with a conductive adhesion layer therebetween, and includes first marks formed on the first printed circuit board and second marks and formed on the second printed circuit board. The area enclosed by the perimeter of one set of marks out of the first marks and the second marks is greater than the area enclosed by the perimeter of the other set of marks, and with the printed circuit boards in an allowable state of connection, at least a portion of the region enclosed by the perimeter of the other set of marks is located within the region enclosed by the perimeter of the one set of marks when viewed in a direction of stacking of the printed circuit boards.

### CROSS-REFERENCE TO RELATED APPLICATION

The Present application is a Continuing Application based on International Application PCT/JP2013/003958 filed on Jun. 25, 2013, which, in turn, claims the priority from Japanese Patent Application No. 2012-147329 filed on Jun. 29, 2012, the entire disclosure of these earlier applications being herein incorporated by reference.

### TECHNICAL FIELD

The present invention relates to a printed circuit board connection structure.

### BACKGROUND ART

In recent years, a structure to connect printed circuit boards has often been used in electronic devices (for example, see Patent Literature 1). The method illustrated in FIG. 6 provides a known example of a method for connecting printed circuit boards in such a printed circuit board connection structure.

In the method for connection illustrated in FIG. 6, a rigid printed circuit board 110 is mounted pattern side up onto a substrate stage 120, and a flexible printed circuit board 130 is mounted pattern side down onto an adjustment stage 140. For example as illustrated in the plan view in FIG. 7(a), recognition marks 114 and 115 for alignment are respectively formed integrally with connection terminals 112 and 113 at either edge of a connection terminal row 111 on the pattern side in the rigid printed circuit board 110. Similarly, for example as illustrated in the back view of FIG. 7(b), recognition marks 134 and 135 for alignment are respectively formed integrally with connection terminals 132 and 133 at either edge of a connection terminal row 131 on the opposing pattern side in the flexible printed circuit board 130 as well. The recognition marks 114 and 115 and the recognition marks 134 and 135 are formed to have the same shape and area. To clarify the illustration in FIG. 6, the connection terminals in the flexible printed circuit board 130 are omitted from the drawing.

In FIG. 6, a conductive adhesive 150 is applied to the connection terminal row 111 in the rigid printed circuit board 110. When connecting the rigid printed circuit board 110 and the flexible printed circuit board 130, first, as illustrated in FIG. 6, the connection terminal row 111 and the connection terminal row 131 are aligned by being overlapped with a predetermined gap therebetween. The connection terminal row 111 and connection terminal row 131 are aligned by capturing an image of the overlapping region thereof with a camera 160 for recognition, and while observing the image, using the adjustment stage 140 to turn the flexible printed circuit board 130 in a plane and move the flexible printed circuit board 130 in two dimensions. In this way, as illustrated by the partial enlargement in FIG. 8(b), the connection terminal row 131 and connection terminal row 111, the recognition mark 134 and recognition mark 114, and the recognition mark 135 and recognition mark 115 are adjusted to overlap each other perfectly. Note that the flexible printed circuit board 130 has sufficient optical transparency to allow for imaging of the rigid printed circuit board 110 located below.

Subsequently, as illustrated in FIG. 9, the connection terminal row 131 portion of the flexible printed circuit board 130 is pushed down by a clamping head 170 to clamp and connect the connection terminal row 131 to the connection terminal row 111 with the conductive adhesive 150 therebetween. As in FIG. 6, to clarify the illustration in FIG. 9, the connection terminals in the flexible printed circuit board 130 are omitted from the drawing.

### CITATION LIST

### Patent Literature

PTL 1: JP2012-28745A

### SUMMARY OF INVENTION

### Technical Problem

In the above-described method for connection, the rigid printed circuit board 110 and the flexible printed circuit board 130 are aligned with a predetermined gap therebetween as illustrated in FIG. 6, and subsequently, the connection terminal row 131 portion of the flexible printed circuit board 130 is pushed down by the clamping head 170, as illustrated in FIG. 9. Therefore, the flexible printed circuit board 130 is bent downwards, and the connection terminal row 131 is clamped and connected to the connection terminal row 111 of the rigid printed circuit board 110 in a state misaligned by ΔL from the initial position.

As a result, during alignment, even if the recognition marks 134 and 135 on the flexible printed circuit board 130 side are aligned to overlap perfectly with the corresponding recognition marks 114 and 115 on the rigid printed circuit board 110 side, as illustrated in FIG. 8(a), the connection structure after clamping is such that the recognition marks 134 and 135 are misaligned with the corresponding recognition marks 114 and 115, as illustrated by the partial enlargement in FIG. 10(b). Therefore, there is a risk that the length of the flexible printed circuit board 130 extending from the rigid printed circuit board 110 will deviate from an acceptable value for the design, adversely affecting wiring or the like of the flexible printed circuit board 130 during subsequent assembly or the like.

One foreseeable way of addressing this problem is to align the marks so that the recognition marks 134 and 135 are offset with respect to the corresponding recognition marks 114 and 115 by the distance of misalignment after clamping. This approach, however, makes alignment troublesome and time-consuming and also lowers the yield. Note that this problem also occurs in a structure to connect flexible printed circuit boards to each other.

### Solution to Problem

A printed circuit board connection structure according to the present invention is formed by clamping and connecting a first printed circuit board and a second printed circuit board, at least one of which is a flexible printed circuit board, with a conductive adhesion layer therebetween, the printed circuit board connection structure comprising: a first mark formed on the first printed circuit board; and a second mark formed on the second printed circuit board, wherein an area enclosed by a perimeter of one mark out of the first mark and the second mark is greater than an area enclosed by a perimeter of the other mark, and with the printed circuit board and the second printed circuit board in an allowable state of connection, at least a portion of a region enclosed by the perimeter of the other mark is located within a region enclosed by the perimeter of the one mark when viewed in a direction of stacking of the printed circuit board and the second printed circuit board.

The first printed circuit board is preferably a rigid printed circuit board, the second printed circuit board is preferably a flexible printed circuit board, and the area enclosed by the perimeter of the first mark is preferably greater than the area enclosed by the perimeter of the second mark.

With the first printed circuit board and the second printed circuit board in the allowable state of connection, a portion of the first mark preferably protrudes outward from the second printed circuit board when viewed in the direction of stacking.

### BRIEF DESCRIPTION OF DRAWINGS

The present invention will be further described below with reference to the accompanying drawings, within:

FIG. 1(a) is a plan view illustrating the structure of the main parts of a printed circuit board connection structure according to Embodiment 1;

FIG. 1(b) is a partial enlargement of the structure of the printed circuit board connection in FIG. 1(a) corresponding to the oval shown in dashed lines in FIG. 1(a);

FIG. 2 illustrates a method for connecting the printed circuit boards in FIG. 1(a);

FIG. 3(a) illustrates alignment of the printed circuit boards in FIG. 1(a);

FIG. 3(b) is a partial enlargement of the alignment of the printed circuit boards in FIG. 3(a) corresponding to the oval shown in dashed lines in FIG. 3(a);

FIG. 4 illustrates a process for connecting the printed circuit boards in FIG. 1(a);

FIG. 5 is a partial plan view illustrating the structure of the main parts of a printed circuit board connection structure according to Embodiment 2;

FIG. 6 illustrates a method for connecting printed circuit boards;

FIG. 7(a) illustrates the connection terminal rows and recognition marks formed on the printed circuit boards in FIG. 6;

FIG. 7(b) illustrates the back view of the connection terminal rows and recognition marks formed on the printed circuit boards in FIG. 6;

FIG. 8(a) illustrates alignment of the printed circuit boards in FIG. 6;

FIG. 8(b) is a partial enlargement of the alignment of the printed circuit boards in FIG. 8(a) corresponding to the circle shown in dashed lines in FIG. 8(a);

FIG. 9 illustrates a process for connecting the printed circuit boards in FIG. 6; and

FIG. 10(a) illustrates a conventional printed circuit board connection structure;

FIG. 10(b) is a partial enlargement of the alignment of the printed circuit boards in FIG. 10(a) corresponding to the circle shown in dashed lines in FIG. 10(a).

### DESCRIPTION OF EMBODIMENTS

The following describes embodiments of the present invention with reference to the drawings.

### Embodiment 1

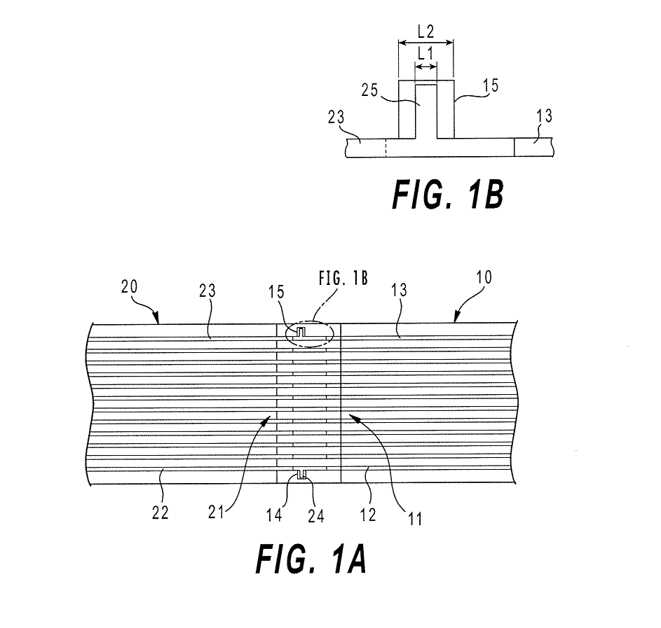

FIG. 1(a) is a plan view illustrating the structure of the main parts of a printed circuit board connection structure according to Embodiment 1 of the present invention. The connection structure according to the present embodiment includes a rigid printed circuit board 10 and a flexible printed circuit board 20. Recognition marks 14 and 15 for alignment, which constitute the first mark, are respectively formed integrally with connection terminals 12 and 13 at either edge of a connection terminal row 11 on the pattern side in the rigid printed circuit board 10. The recognition marks 14 and 15 protrude outward from the connection terminal row 11. As in the rigid printed circuit board 10, recognition marks 24 and 25 for alignment, which constitute the second mark, are respectively formed integrally with connection terminals 22 and 23 at either edge of a connection terminal row 21 on the pattern side in the flexible printed circuit board 20. The recognition marks 24 and 25 protrude outward from the connection terminal row 21.

In the present embodiment, the recognition marks 14 and 15 protrude in a direction perpendicular to the direction of elongation of the corresponding connection terminals 12 and 13 and have a solid rectangular shape. Similarly, the recognition marks 24 and 25 protrude in a direction perpendicular to the direction of elongation of the corresponding connection terminals 22 and 23 and have a solid rectangular shape.

The recognition marks 14 and 15 are formed to have a larger area than the recognition marks 24 and 25, so that the recognition marks 24 and 25 are positioned within the region of the corresponding recognition marks 14 and 15 when viewed in the direction of stacking of the rigid printed circuit board 10 and the flexible printed circuit board 20 with the rigid printed circuit board 10 and the flexible printed circuit board 20 in a state of being connected within an acceptable range of the design value. In other words, as illustrated by the partial enlargement in FIG. 1(b), with the dimension of the recognition mark 25 in the direction of length of the connection terminal 23 being L1, then the corresponding dimension L2 of the recognition mark 15 in the direction of length of the connection terminal 13 is formed to be greater towards the tip of the connection terminal 13 by taking into consideration L1, the tolerance for the design length of the flexible printed board 20, and the below-described misalignment ΔL when clamping the flexible printed circuit board 20. The same is true for the recognition mark 14.

In this way, it is easy to recognize that the rigid printed circuit board 10 and the flexible printed circuit board 20 are connected within an acceptable range of the design value if the recognition marks 24 and 25 are located within the region of the corresponding recognition marks 14 and 15. Note that the recognition marks 24 and 25 may be formed to be shifted towards the tip of the connection terminals 22 and 23 by the below-described amount of misalignment ΔL when clamping the flexible printed circuit board 20.

Next, a method for connecting the rigid printed circuit board 10 and the flexible printed circuit board 20 to obtain the connection structure according to the present embodiment is described.

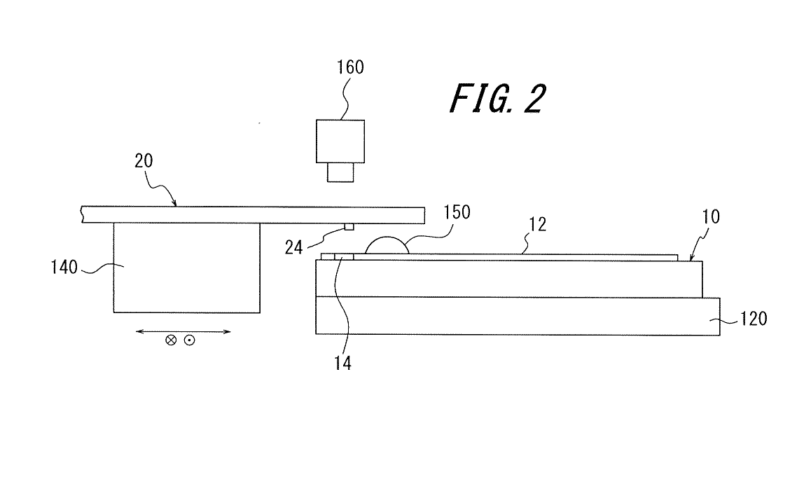

As illustrated in FIG. 2, the rigid printed circuit board 10 is first mounted pattern side up onto a substrate stage 120, and the flexible printed circuit board 20 is mounted pattern side down onto an adjustment stage 140. A conductive adhesive 150 forming a conductive adhesion layer is applied to the connection terminal row 11 in the rigid printed circuit board 10. The adjustment stage 140 is positioned to be a predetermined distance higher than the substrate stage 120 so that, when the flexible printed circuit board 20 is mounted on the adjustment stage 140, the conductive adhesive 150 on the rigid printed circuit board 10 does not contact the flexible printed circuit board 20. To clarify the illustration in FIG. 2, the connection terminals in the flexible printed circuit board 20 are omitted from the drawing.

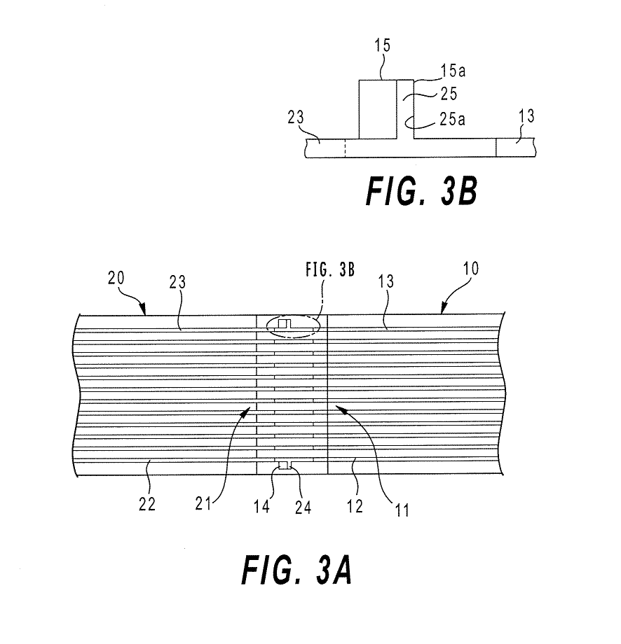

Next, an image of the overlapping region between the connection terminal row 11 of the rigid printed circuit board 10 and the connection terminal row 21 of the flexible printed circuit board 20 is captured with a camera 160 for recognition, and while the image is observed, the flexible printed circuit board 130 is turned in a plane and moved in two dimensions, with the adjustment stage 140. In this way, as illustrated in FIG. 3(a), the recognition mark 24 and recognition mark 14 are respectively aligned with the recognition mark 25 and recognition mark 15. During alignment, as illustrated by the partial enlargement of alignment between the recognition mark 25 and the recognition mark 15 in FIG. 3(a), the connection terminal 23 of the flexible printed circuit board 20 is matched to (overlapped with) the connection terminal 13 of the rigid printed circuit board 10, and an edge 25a of the recognition mark 25 closer to the tip of the connection terminal 23 is matched to an edge 15a of the recognition mark 15 further away from the tip of the connection terminal 13. The recognition mark 24 is aligned similarly with respect to the recognition mark 14. Note that the flexible printed circuit board 20 is formed to have sufficient optical transparency to allow for imaging of the rigid printed circuit board 10 located below.

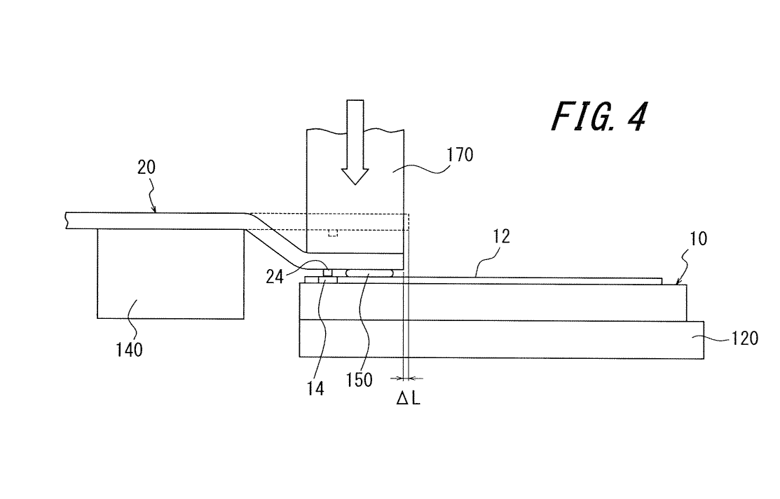

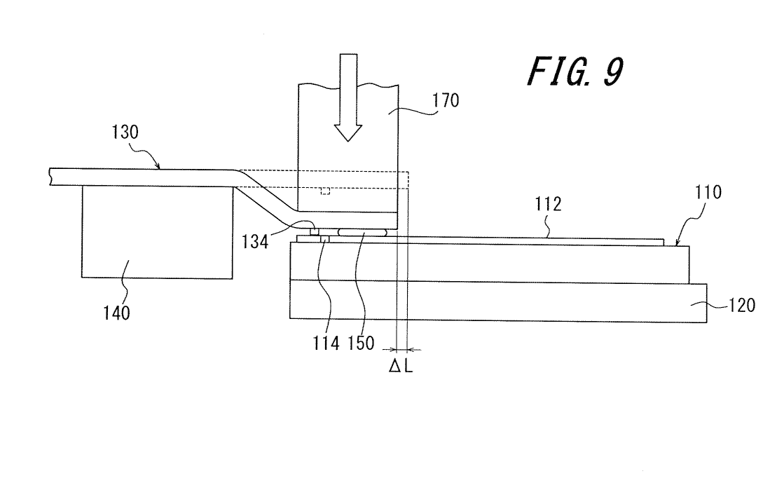

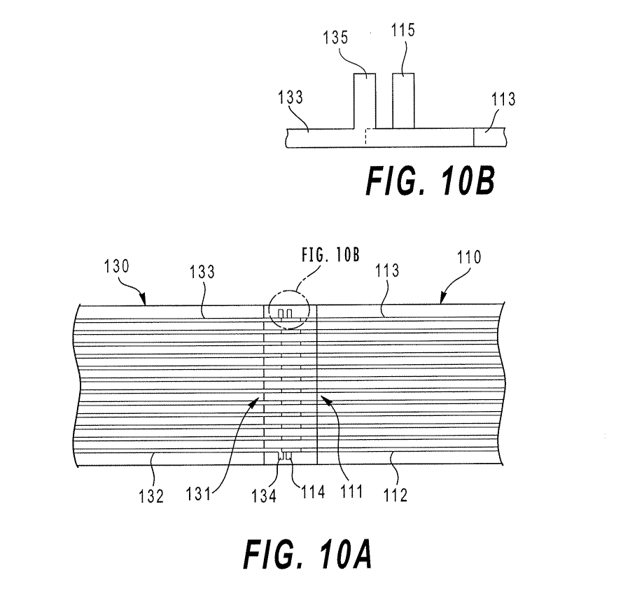

Subsequently, as illustrated in FIG. 4, the connection terminal row 21 portion of the flexible printed circuit board 20 is pushed down by a clamping head 170 to clamp and connect the connection terminal row 21 to the connection terminal row 11 with the conductive adhesive 150 therebetween. Therefore, as in the case in FIG. 9, the flexible printed circuit board 20 is bent downwards in this case as well, and the connection terminal row 21 is clamped and connected to the connection terminal row 11 of the rigid printed circuit board 10 in a state misaligned by ΔL from the initial position. As in FIG. 2, to clarify the illustration in FIG. 4, the connection terminals in the flexible printed circuit board 20 are omitted from the drawing.

As described above, according to the connection structure of the present embodiment, by matching the edges of the recognition marks 24 and 25 closer to the tip of the connection terminals 22 and 23 in the flexible printed circuit board 20 to the edges of the corresponding recognition marks 14 and 15 further away from the tip of the connection terminals 12 and 13 in the rigid printed circuit board 10, the flexible printed circuit board 20 can be aligned with the rigid printed circuit board 10. Alignment thus becomes easy. Furthermore, the recognition marks 24 and 25 and the recognition marks 14 and 15 are formed taking into consideration the misalignment ΔL when clamping and connecting the flexible printed circuit board 20, and in a state with the recognition marks 24 and 25 located within the region of the corresponding recognition marks 14 and 15, the rigid printed circuit board 10 and the flexible printed circuit board 20 are connected with an acceptable range of the design value. Accordingly, the rigid printed circuit board 10 and the flexible printed circuit board 20 can be connected easily and accurately, the yield can be increased, and the state of connection can easily be recognized.

### Embodiment 2

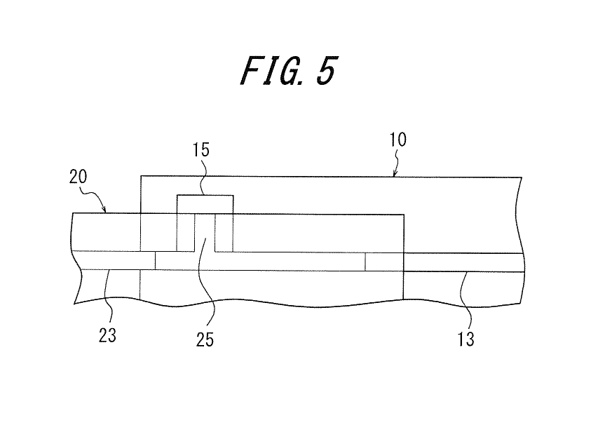

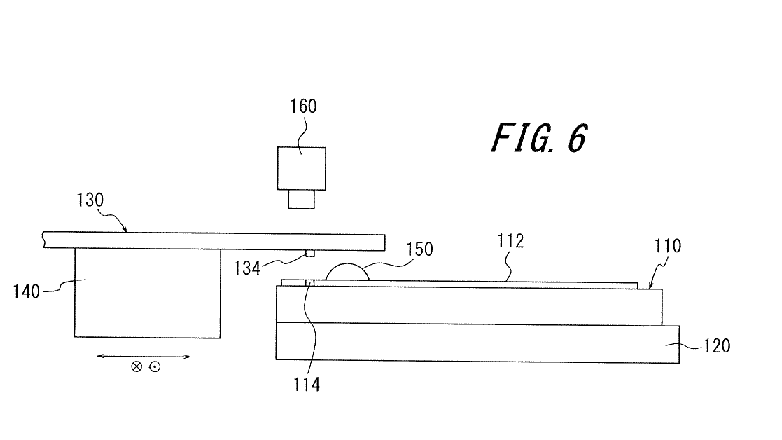

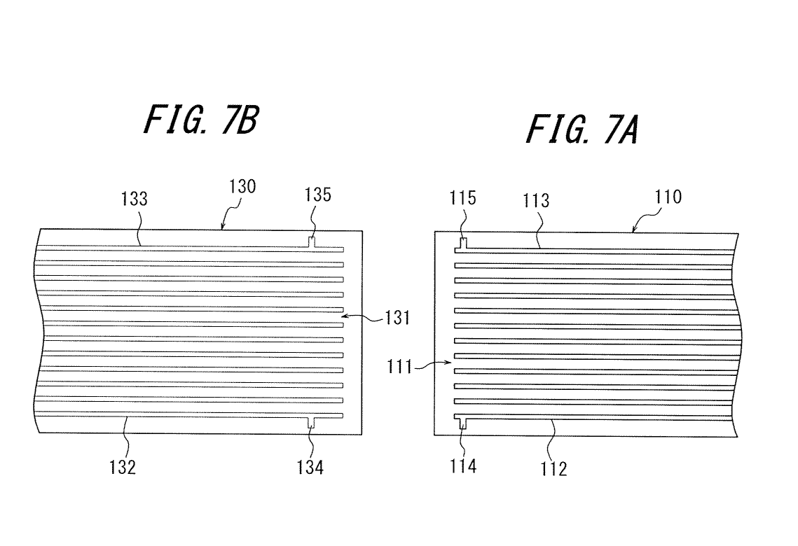

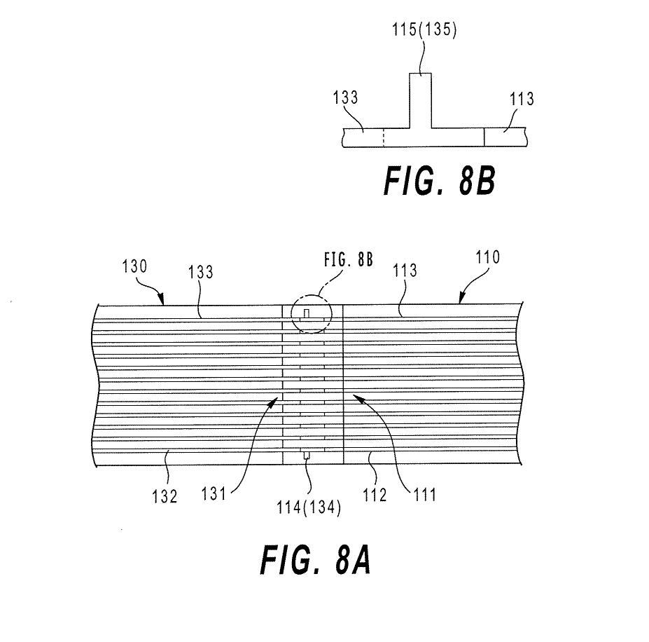

FIG. 5 is a partial plan view illustrating the structure of the main parts of a printed circuit board connection structure according to Embodiment 2 of the resent invention. The connection structure according to the present embodiment is the same as the connection structure of Embodiment 1, except that with the rigid printed circuit board 10 and the flexible printed circuit board 20 in an allowable state of connection, a portion of the recognition marks 14 and 15 protrudes outward from the flexible printed circuit board 20 when viewed in a direction of stacking of the printed circuit boards. In other words, the dimension of the flexible printed circuit board 20 in the direction of the connection terminal row 21 is shorter than the dimension of the rigid printed circuit board 10 in the direction of the connection terminal row 11. Note that in FIG. 5, only an enlargement of the portion including the recognition mark 15 and the recognition mark 25 is illustrated.

According to the connection structure of the present embodiment, similar effects to those of Embodiment 1 are obtained. Additionally, even when the optical transparency of the flexible printed circuit board 20 is low, making it difficult to see the rigid printed circuit board 10 below, alignment is made easier since the large recognition marks 14 and 15 of the rigid printed circuit board 10 protrude outward from the flexible printed circuit board 20.

The present invention is not limited to the above embodiments, and a variety of modifications and changes are possible. For example, in the above embodiments, the recognition marks 24 and 25 of the flexible printed circuit board 20 may be formed to be larger than the recognition marks 14 and 15 of the rigid printed circuit board 10. In this case, the recognition marks 24 and 25 may be aligned with the recognition marks 14 and 15 before clamping and connecting by matching the edges of the recognition marks 24 and 25 further away from the tip of the connection terminals 22 and 23 to the edges of the corresponding recognition marks 14 and 15 closer to the tip of the connection terminals 12 and 13.

In the above embodiments, the recognition marks on each printed circuit board are not limited to a solid rectangular shape that protrudes in a direction perpendicular to the direction of elongation of the corresponding connection terminal and may be formed as any solid or hollow shape that protrudes in any direction from the connection terminal row. Therefore, the recognition marks may, for example, be solid or hollow shape with a curved perimeter. The recognition marks in each printed circuit board are not limited to the case of the entire region enclosed by the perimeter of the other mark being located within the region enclosed by the perimeter of the one mark when viewed in the direction of stacking with the printed circuit boards in an allowable state of connection. Rather, a portion of the region enclosed by the perimeter of the other mark may be located within a predetermined portion of the region enclosed by the perimeter of the one mark.

Furthermore, the present invention is not limited to a connection structure for a rigid printed circuit board and a flexible printed circuit board and may be similarly applied to a connection structure for flexible printed circuit boards. The recognition marks in the printed circuit boards are not limited to being formed integrally with the connection terminals but rather may be formed separately and independently from the connection terminals. Moreover, the recognition marks and the printed circuit boards are not limited to the case of one recognition mark being formed on each side of the connection terminal row. A plurality of recognition marks may be formed, or one or more recognition marks may be formed on only one side of the connection terminal row. The conductive adhesion layer connecting the printed circuit boards is not limited to conductive adhesive and may be formed with a conductive adhesion film such as anisotropic conductive film (ACF) or with a different conductive adhesion material.

### REFERENCE SIGNS LIST

10: Rigid printed circuit board

11: Connection terminal row

12, 13: Connection terminal

14, 15: Recognition mark

20: Flexible printed circuit board

21: Connection terminal row

22, 23: Connection terminal

24, 25: Recognition mark

120: Substrate stage

140: Adjustment stage

150: Conductive adhesive

160: Camera for recognition

170: Clamping head

1. A printed circuit board connection structure formed by clamping and connecting a first printed circuit board and a second printed circuit board, at least one of which is a flexible printed circuit board, with a conductive adhesion layer therebetween, the printed circuit board connection structure comprising:
a first mark formed on the first printed circuit board; and
a second mark formed on the second printed circuit board, wherein
an area enclosed by a perimeter of one mark out of the first mark and the second mark is greater than an area enclosed by a perimeter of the other mark, and with the first printed circuit board and the second printed circuit board in an allowable state of connection, at least a portion of a region enclosed by the perimeter of the other mark is located within a region enclosed by the perimeter of the one mark when viewed in a direction of stacking of the first printed circuit board and the second printed circuit board.

2. The printed circuit board connection structure according to claim 1, wherein
the first printed circuit board is a rigid printed circuit board,
the second printed circuit board is a flexible printed circuit board, and
the area enclosed by the perimeter of the first mark is greater than the area enclosed by the perimeter of the second mark.

3. The printed circuit board connection structure according to claim 1, wherein with the first printed circuit board and the second printed circuit board in the allowable state of connection, a portion of the first mark protrudes outward from the second printed circuit board when viewed in the direction of stacking.
